(19) United States
(12) Patent Application Publication
(10) Pub. No.: US 2007/0160870 A1
(43) Pub. Date: Jul. 12, 2007

(54) Phosphorescent organic light-emitting diodes

(75) Inventors: Chen-Ping Yu, Longtan Township (TW); Chung-Wen Ko, Sijhih City (TW); Tswen-Hsin Liu, Jhudong Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/368,915

(22) Filed: Mar. 6, 2006

(30) Foreign Application Priority Data
Nov. 10, 2005 (TW) 94139469

(51) Int. Cl. H01L 51/54

(52) U.S. Cl. 428/690; 428/917; 313/504; 313/506; 257/102; 257/103; 257/E51.051; 257/E51.043; 257/E51.05; 257/E51.044

(57) ABSTRACT

This invention discloses a phosphorescent OLED having a light emitting layer thereof contains a host material and dopant materials comprising phosphorescent dopant and triarylamine. The triarylamine has a HOMO value less than that of the host material, as Balq (5.7 eV), thereby decreasing driving voltage and increasing lifetime of the OLED devices.

### BACKGROUND OF THE INVENTION

1. Field of the Invention

The present invention relates to organic light-emitting devices, and in particular relates to phosphorescent light-emitting devices.

2. Description of the Related Art

Organic light-emitting diodes (OLED) have become the favored devices for use in the flat panel display field since their 1987 invention by Kodak. OLEDs have advantages as high brightness, light weight, thin structure, low power consumption, substantially free of backlightines, wide viewing angle, simple process, and outstanding response time.

The mechanism of electroluminescence in OLED is electrons and holes injected from a cathode and an anode, respectively, to the device. When the electrons and the holes combine to form excitons in a light-emitting layer, and the energy of the excitons is then transferred, causing molecules to emit light.

In a conventional OLED, a light-emitting layer is disposed between the cathode and the anode. An electron injection layer and an electron transporting layer may be optionally disposed between the cathode and the light-emitting layer. A hole injection layer and a hole transporting layer may also be optionally disposed between the anode and the light-emitting layer. Many modifications of the concept relate to multi-layer structures. For example, buffer layers can be applied for enhancing the probability of the combinations of the holes and the electrons in the light-emitting layer. Mixing layers is another modification. Such as U.S. Pat. No. 6,803,720, the phosphorescent dopant, the material of the hole transporting layer, and the material of the electron transporting layer are mixed to form the light-emitting layer; the OLED has no hole transporting layer, but has an electron transporting layer. Another kind of mixed layer is disclosed in U.S. Pat. No. 6,734,457, the phosphorescent dopant and the material of the electron transporting layer are mixed together to form the light-emitting layer; the OLED has no electron transporting layer, but has a hole transporting layer.

The invention aims to achieve higher luminescence yield, higher brightness, longer life time, and lower power consumption.

### BRIEF SUMMARY OF INVENTION

The invention provides a phosphorescent organic light-emitting diode, comprising an anode, a cathode; and a light-emitting layer disposed between the cathode and the anode. The light-emitting layer comprises a phosphorescent host material and dopants, wherein the dopants comprise a phosphorescent dopant and a triarylamine.

The invention further provides a display apparatus, comprising a phosphorescent OLED as described above and a driving circuit coupled to the phosphorescent OLED for driving the same.

A detailed description is given in the following embodiments with reference to the accompanying drawings.

### BRIEF DESCRIPTION OF DRAWINGS

The present invention can be more fully understood by reading the subsequent detailed description and examples with references made to the accompanying drawings, wherein:

FIG. 1 shows a cross section of Examples 1-7 of the present invention;

FIG. 2 shows a cross section of Comparative Example 1-2;

FIG. 3 shows a schematic view showing current density versus driving voltage of Example 7 and Comparative example 2;

FIG. 4 shows a schematic view showing brightness versus driving voltage of Example 7 and Comparative example 2;

FIG. 5 shows a schematic view showing lifetime of Example 7 and Comparative example 2;

FIG. 6 is a diagram showing an embodiment of a display apparatus;

FIG. 7 is a diagram showing the energy level between the hole transporting and the light-emitting layer of the hole transferring from these two layers of Comparative example 1 and 2.

FIG. 8 is a diagram showing the energy level between the hole transporting and the light-emitting layer of the hole transferring from these two layers of Example 1-7.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The OLED structure of the provided Examples comprises an anode 13 on a substrate 11, a cathode 19, and a light-emitting layer 17 disposed between the anode 13 and the cathode 19.

The cathode 19 and the anode 13 of Examples of the invention may be the same or different, and include, but are not limited to metal, alloy, transparent metal oxide, or mixtures thereof. At least one of the cathode 19 and the anode 13 must be transparent.

The phosphorescent OLED of the invention further comprises a hole injection layer (HIL) 15 or a hole transporting layer (HTL) 16 disposed between the light-emitting layer 17 and the anode 13, and an electron injection layer (EIL, not shown in the figure) and an electron transporting layer (ETL) 18 disposed between the cathode 19 and the light-emitting layer 17. HIL may comprise polyfluorocarbohydride, porphyrin, or p-doped amino derivatives. Suitable porphrin comprises metallophthalocyanine, including copper phthalocyanine.

Examples of the HTL may be amino polymer, comprising N,N′-bis(1-naphyl)-N,N′-diphenyl-1,1′-biphenyl-4,4′-diamine (NPB), N,N′-diphenyl-N,N′-bis(3-methlphenyl)-(1,1′-biphenyl)-4,4′-diamine (TPD), 2T-NATA, or derivatives thereof. The HTL has a preferred thickness from 50 to 500 angstroms.

The EIL (not shown in the Figure) may be alkali metal halides, alkaline earth metal halides, alkali metal oxide, or metal carbonate. Preferred EIL comprises LiF, CsF, NaF, CaF₂, Li₂O, Cs₂O, Na₂O, Li₂CO₃, Cs₂CO₃, Na₂CO₃, and has a preferred thickness from 5 to 50 angstroms.

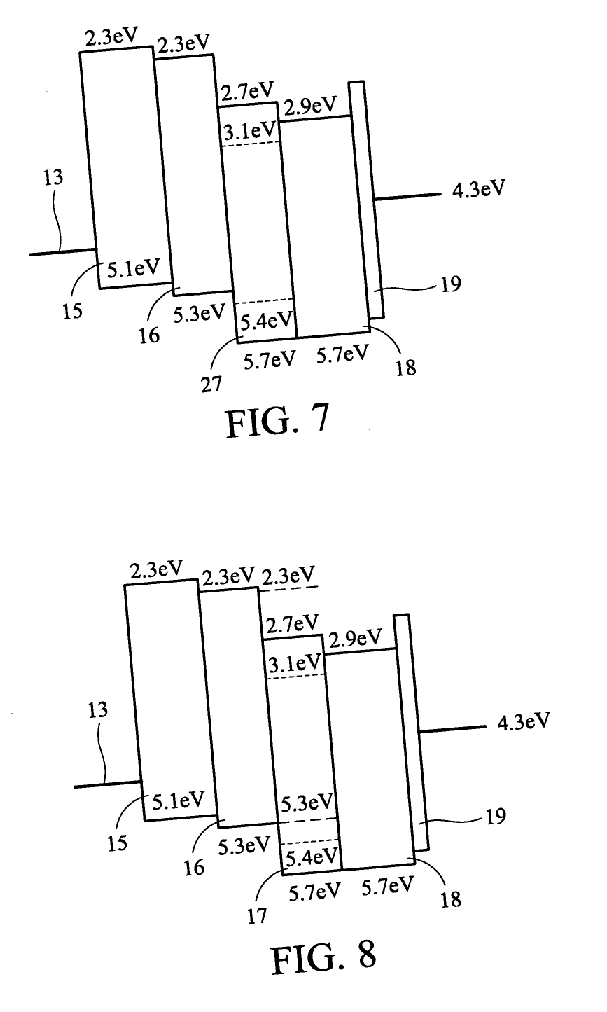

The light-emitting layer 17 has a preferred thickness from 200 to 600 angstroms, comprising a phosphorescent host material and dopants, wherein the dopants comprise a phosphorescent dopant and a triarylamine. A preferred volume ratio of the phosphorescent host material to the triarylamine is from 99:1 to 50:50. A preferred volume ratio of the phosphorescent host material and the triaryamine to the dopant materials is from 100:1 to 100:30. The phosphorescent host material comprises asymmetric aluminum complex, such as bis(2-methyl-8-quinolinolato)(p-phenylphenolato)aluminum (Balq) or 8-(hydroxyquinoline)-4-(phenylphenol) aluminum, or carbazoles, such as 4,4′-N,N′-dicarbazole-biphenyl (CBP) or its derivatives. The phosphorescent dopant may comprise a luminescent dopant such as Ir complex or Pt complex. According to the invention, the Highest Occupied Molecular Orbital (HOMO) of the triarylamine must be less than that of the phosphorescent host material, for example, 5.7 eV of Balq. This means that the hole mobility of the triarylamine is faster than that of the phosphorescent host material. As an energy level diagram shown in FIG. 7, when the holes are transported from the hole transporting layer (HTL) 16 to the light-emitting layer 27, the larger energy gap of the HOMO between the HTL and the light-emitting layer causes the larger driving voltage. As the energy level diagram of FIG. 8 shows, when the holes are transported from the hole transporting layer (HTL) 16 to light-emitting layer 17, the triarylamine with lower HOMO is doped into the light-emitting layer 17, thus decreasing the driving voltage by reducing the energy gap between the HTL 16 and the light-emitting layer 17. The preferred arylamine has a biphenyl group as its symmetric center, comprising N,N′-Bis(naphthalen-1-yl)-N,N′-bis(phenyl)benzidine (NPB), N,N,N′N′-tetranaphthalyl-biphenyl-4,4′-diamine (HT2), or derivatives thereof. The other preferred arylamine has a fluorene group as its symmetric center, comprising N,N′-bis(naphthalen-1-yl)-N,N′-diphenyl-9,9-dimethylfluorene (DMFL-NPB), spiro-NPB, spiro-TAD, or derivatives thereof. Experiments show the triarylamine doped into the light-emitting layer may reduce driving voltage. Examples of the invention reduce the driving voltage from 0.4 to 0.8 V, thus prolonging device lifetime.

Structures of these triarylamines described above are shown below:

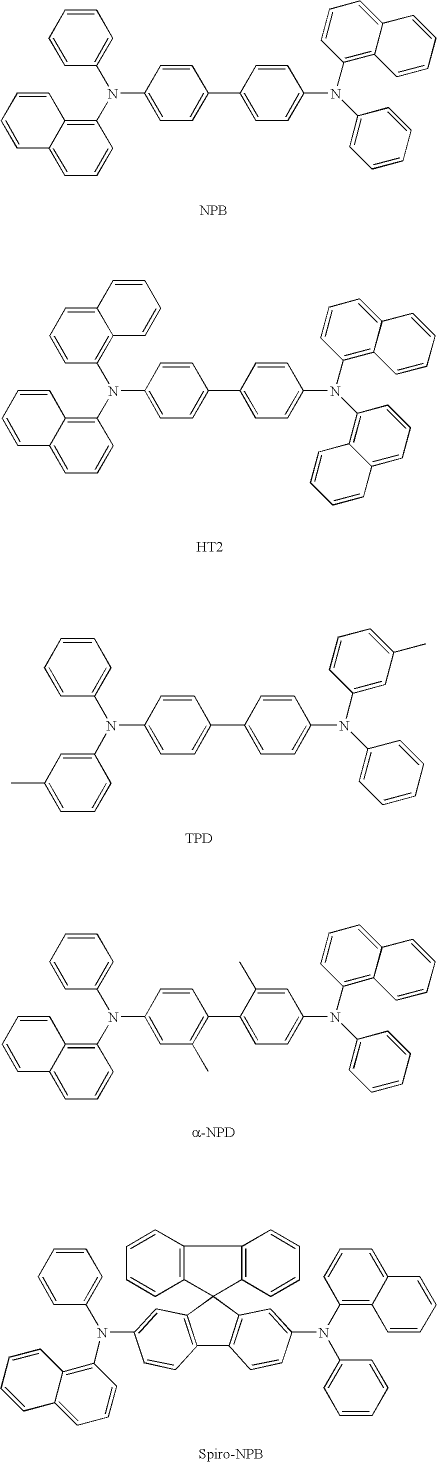

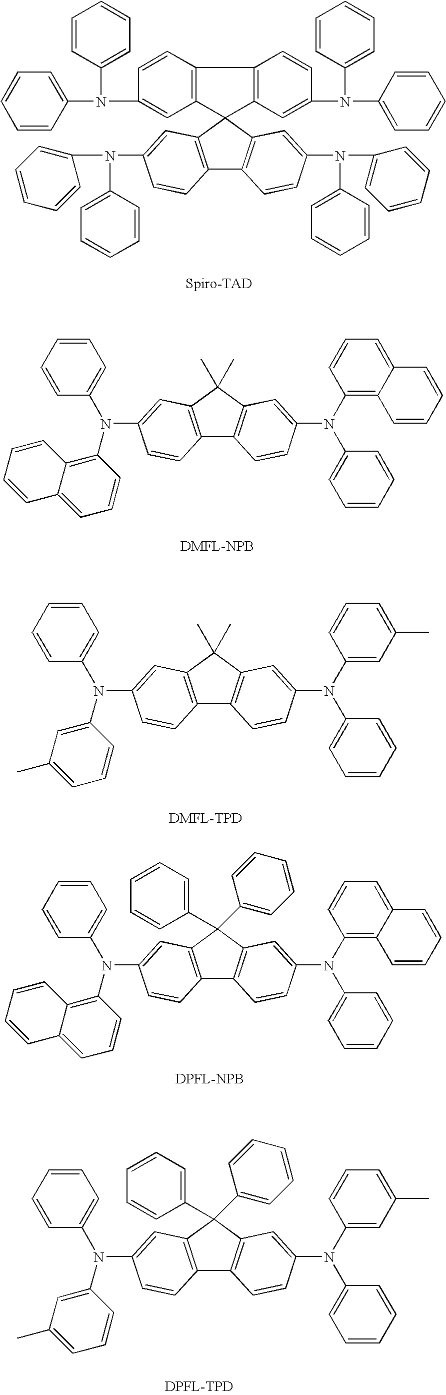

The HOMO of these triarylamines are shown in Table 1.

TABLE 1

| Triaryamine | HOMO value (eV) |
|---|---|
| BAlq | 5.70 |
| NPB | 5.32 |
| HT2 | 5.50 |
| Spiro TAD | 5.35 |
| Spiro NPB | 5.36 |
| DPFL NPB | 5.35 |

FIG. 6 is a diagram showing a display apparatus of the invention, comprising the above phosphorescent OLED device, and a driving circuit coupled to the phosphorescent OLED for driving the same. The preferred driving circuit is a thin film transistor (TFT).

### DEVICE EXAMPLES AND COMPARATIVE EXAMPLES

### Examples 1-3

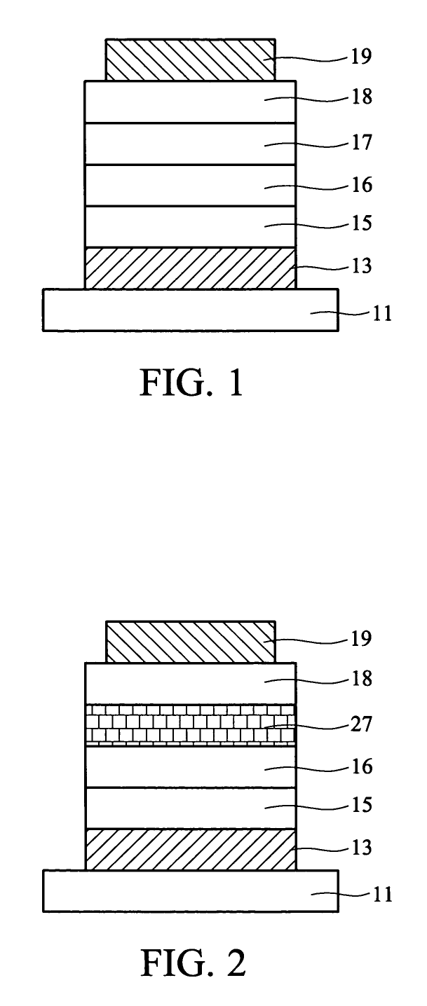

FIG. 1 shows a cross section view of Examples 1-3:

Anode 13: indium tin oxide (ITO) on a transparent substrate 11;

HIL 15: 4,4′,4″-tri(N-(2-naphthyl)-N-aniline)-triphenyl amine (2T-NATA) of about 60 nm;

HTL 16: NPB of about 20 nm;

Light-emitting layer 17: phosphorescent host material (Balq) and dopants, wherein the dopants comprised a phosphorescent dopant (Ir(piq)₂(acac))and a triarylamine (NPB); the phosphorescent host material, the phosphorescent dopant, and the triarylamine had a volume ratio of 100:12:x, wherein the x was 10 in Example 1, 30 in Example 2, 50 in Example 3; the light-emitting layer had a thickness of about 40 nm;

ETL 18: Alq₃ and Li had a molar ratio of 1:1, and the ETL had a thickness of about 30 nm;

EIL (not shown): LiF of about 1 nm; and

Cathode 19: aluminum of about 150 nm.

The structure of the 2T-NATA and Balq were shown as below:

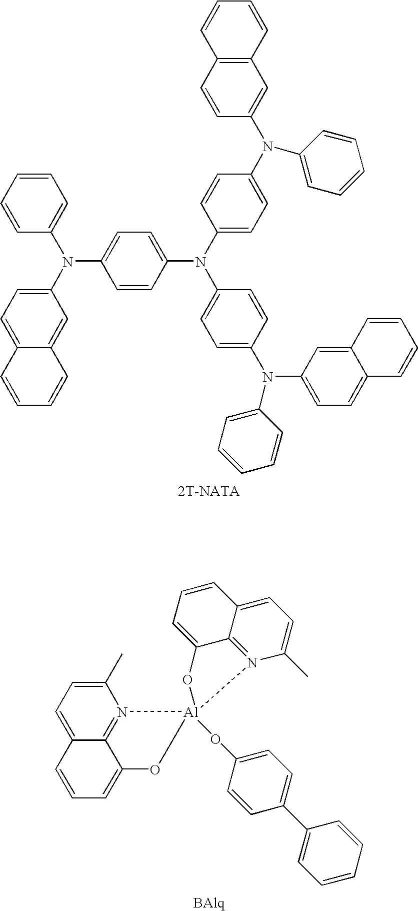

### Examples 4-6

FIG. 1 shows a cross section view of Examples 4-6.

Anode 13: ITO on a transparent substrate 11;

HIL 15: 2T-NATA of about 60 nm;

HTL 16: NPB of about 20 nm;

Light-emitting layer 17: phosphorescent host material (Balq) and dopants, wherein the dopants comprised a phosphorescent dopant (Ir(piq)₂(acac))and a triarylamine (spiro-TAD); the phosphorescent host material, the phosphorescent dopant, and the triarylamine had a volume ratio of 100:12:x, wherein the x was 5 in Example 4, 10 in Example 5, 20 in Example 6; the light-emitting layer had a thickness of about 40 nm;

ETL 18: Alq₃ and Li have a molar ratio of 1:1, and the ETL had a thickness of about 30 nm;

EIL (not shown): LiF of about 1 nm; and

Cathode 19: aluminum of about 150 nm.

### Comparative Example 1

FIG. 2 shows a cross section view of Comparative example 1.

Anode 13: ITO on a transparent substrate 11;

HIL 15: 2T-NATA of about 60 nm;

HTL 16: NPB of about 20 nm;

Light-emitting layer 27: phosphorescent host material (Balq) and dopants, wherein the dopants comprised a phosphorescent dopant (Ir(piq)₂(acac)); the phosphorescent host material and the phosphorescent dopant had a volume ratio of 100:12; the light-emitting layer had a thickness of about 40 nm;

ETL 18: Alq₃ and Li had a molar ratio of 1:1, and the ETL had a thickness of about 30 nm;

EIL (not shown): LiF of about 1 nm; and

Cathode 19: aluminum of about 150 nm.

The comparisons of the Examples 1-6 and Comparative example 1 are collected in Table 2.

TABLE 2

| | | | Driving | Bright- | Luminance | |
|---|---|---|---|---|---|---|
| Exam- | triaryl- | Doped | voltage | ness | yield | lifetime |
| ple | amine | ratio | (V) | (cd/m²) | (cd/A) | (hour) |
| 1 | NPB | 10 | 5.2 | 1000 | 6.8 | 1000 |
| 2 | NPB | 20 | 5.2 | 1000 | 5.5 | 400 |
| 3 | NPB | 50 | 5.0 | 1000 | 3.1 | 210 |
| 4 | Spiro | 5 | 5.4 | 1000 | 7.2 | — |
| | TAD | | | | | |
| 5 | Spiro | 10 | 5.1 | 1000 | 6.8 | — |
| | TAD | | | | | |
| 6 | Spiro | 20 | 4.8 | 1000 | 3.5 | — |
| | TAD | | | | | |
| Com | none | none | 6.0 | 1000 | 7.0 | 800 |
| Ex 1 | | | | | | |

Note:
the initial brightness was 2000 cd/m^{2.}

Table 2 clearly shows the doped triarylamine prolonging the device lifetime and reducing the driving voltage, but too high concentration doped triarylamine will decrease the luminance yield and the device lifetime. The preferred volume ratio of the phosphorescent host material and the triarylamine is from 99:1 to 50:50.

### Example 7

FIG. 1 shows a cross section view of Example 7.

Anode 13: ITO on a transparent substrate 1 1;

HIL 15: 2T-NATA of about 60 nm;

HTL 16: NPB of about 20 nm;

Light-emitting layer 17: phosphorescent host material (Balq) and dopants, wherein the dopants comprised a phosphorescent dopant (Ir(piq)₂(acac))and a triarylamine (spiro-TAD); the phosphorescent host material, the phosphorescent dopant, and the triarylamine (NPB) had a volume ratio of 100:12:30; the light-emitting layer had a thickness of about 40 nm;

ETL 18: Alq₃ and Li had a molar ratio of 1:1, and the ETL had a thickness of about 30 nm;

EIL (not shown): LiF of about 1 nm; and

Cathode 19: aluminum of about 150 nm.

### Comparative Example 2

FIG. 2 shows a cross section view of Comparative example 2.

Anode 13: ITO on a transparent substrate 11;

HIL 15: 2T-NATA of about 60 nm;

HTL 16: NPB of about 20 nm;

Light-emitting layer 27: phosphorescent host material (Balq) and dopants, wherein the dopants comprised a phosphorescent dopant (Ir(piq)₂(acac)); the phosphorescent host material and the phosphorescent dopant had a volume ratio of 100:12; the light-emitting layer had a thickness of about 40 nm;

ETL 18: Alq₃ and Li had a molar ratio of 1:1, and the ETL had a thickness of about 30 nm;

EIL (not shown): LiF of about 1 nm; and

Cathode 19: aluminum of about 150 nm.

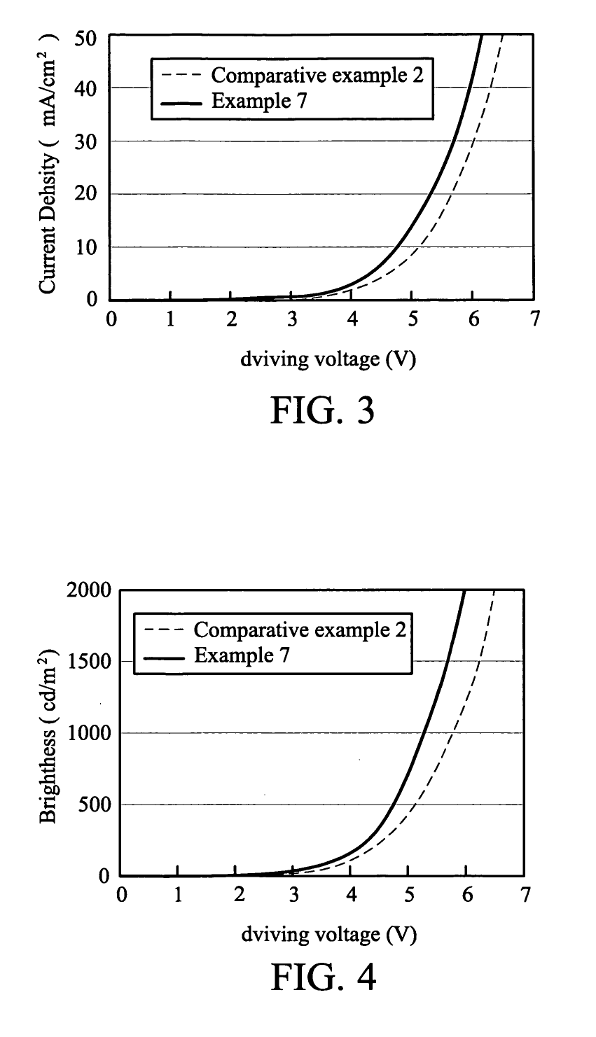

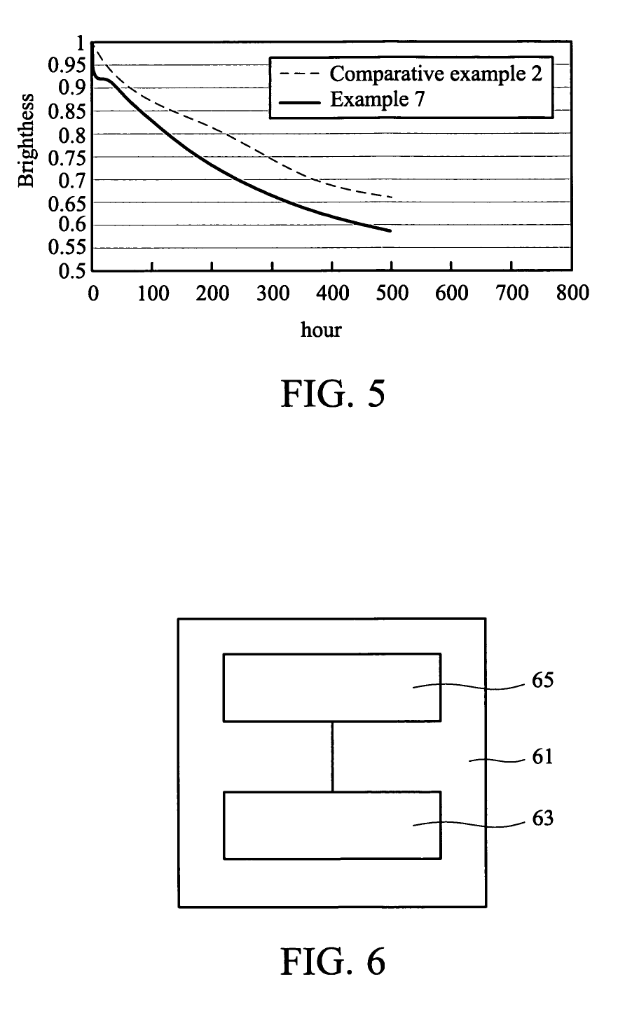

Example 7 and Comparative example 2 are compared as shown in FIGS. 3 and 4 which shows Example 7 having a lower driving voltage. As shown in FIG. 3, when the current density was 20 mA/cm², the driving voltage of Example 7 (5.4 V) was less than that of Comparative example 2 (5.9 V) about 0.5V by the doped triarylamine. As shown in FIG. 4, when the candlepower was 1000 cd/m² in CIE (0.66,0.34) with luminance yield 5.3 cd/A, the driving voltage of Example 7 (5.3 V) was less than Comparative example 2 (5.8 V) about 0.5 V by doped triarylamine, too. FIG. 5 shows the brightness of Example 7 was 66% of the initial brightness after light 500 hours, and that of Comparative example 2 was 58%. As described above, the doped triarylamine enhanced the life time of the device.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phosphorescent organic light-emitting diode (OLED), comprising:
an anode;
a cathode; and
a light-emitting layer, disposed between the cathode and the anode, comprising a phosphorescent host material and dopants, wherein the dopants comprise a phosphorescent dopant and a triarylamine.

2. The phosphorescent OLED as claimed in claim 1, wherein the volume ratio of the phosphorescent host material to the triarylamine is from about 99:1 to about 50:50.

3. The phosphorescent OLED as claimed in claim 1, wherein the volume ratio of the phosphorescent host material and the triaryamine to the dopants is from about 100:1 to about 100:30.

4. The phosphorescent OLED as claimed in claim 1, further comprising a hole transporting layer disposed between the anode and the light-emitting layer, and an electron transporting layer disposed between the cathode and the light-emitting layer.

5. The phosphorescent OLED as claimed in claim 4, further comprising a hole injection layer disposed between the anode and the hole transporting layer, and an electron injection layer disposed between the cathode and the electron transporting layer.

6. The phosphorescent OLED as claimed in claim 1, wherein the light-emitting layer has a thickness from about 200 to about 600 angstroms.

7. The phosphorescent OLED as claimed in claim 1, wherein the phosphorescent host material comprises an asymmetric aluminum complex.

8. The phosphorescent OLED as claimed in claim 7, wherein the asymmetric aluminum complex comprises Balq or 8-(hydroxyquinoline)-4-(phenylphenol) aluminum.

9. The phosphorescent OLED as claimed in claim 1, wherein the phosphorescent host material comprises carbazoles.

10. The phosphorescent OLED as claimed in claim 1, wherein the phosphorescent dopant comprises Ir or Pt complex.

11. The phosphorescent OLED as claimed in claim 7, wherein the triarylamine has a Highest Occupied Molecular Orbital (HOMO) value less than 5.7 eV.

12. The phosphorescent OLED as claimed in claim 11, wherein the triarylamine has a biphenyl group as its symmetric center.

13. The phosphorescent OLED as claimed in claim 11, wherein the triarylamine comprises NPB, HT2, or derivatives thereof.

14. The phosphorescent OLED as claimed in claim 11, wherein the triarylamine has a fluorene group as its symmetric center.

15. The phosphorescent OLED as claimed in claim 14, wherein the triarlamine comprises DMFL-NPB, spiro-NPB, spiro-TAD, or derivatives thereof.

16. The phosphorescent OLED as claimed in claim 1, wherein at least one of the cathode and the anode is a transparent electrode.

17. The phosphorescent OLED as claimed in claim 16, wherein the cathode and the anode independently, comprise metal, alloy, transparent metal oxide, or mixtures thereof.

18. The phosphorescent OLED as claimed in claim 16, wherein the cathode and the anode are made of substantially the same material.

19. The phosphorescent OLED as claimed in claim 16, wherein the cathode and the anode are made of different materials.

20. A display apparatus, comprising:
a phosphorescent OLED of claim 1; and
a driving circuit coupled to the phosphorescent OLED for driving the same.

21. The display apparatus as claimed in claim 20, wherein the driving circuit comprises a thin film transistor.
